(19) United States
(12) Patent Application Publication
(10) Pub. No.: US 2026/0161862 A1
(43) Pub. Date: Jun. 11, 2026

(54) COMPUTER-AIDED WATER WAVE DESIGN

(71) Applicant: WHITEWATER WEST INDUSTRIES LTD., Richmond (CA)

(72) Inventors: Clement GINESTET, Paris (FR); Baptiste René Gérard Robert CAULONQUE, Guéthary (FR)

(21) Appl. No.: 19/414,998

(22) Filed: Dec. 10, 2025

Related U.S. Application Data
(60) Provisional application No. 63/730,359, filed on Dec. 10, 2024.

(51) Int. Cl. G06F 30/28; G06T 7/60

(52) U.S. Cl. CPC G06F 30/28; G06T 7/60; G06T 2207/10016; G06T 2207/30181

(57) ABSTRACT

A device for image processing of a water wave may include an image capture device and a processing device. The image capture device may capture water wave images, in which the water wave images includes water wave image data based on one or more time instances. The processing device may compute a water wave model using the water wave image data; compute artificial water wave parameters using the water wave model; and compute artificial water wave generator input using the artificial water wave parameters, in which the artificial water wave generator input is used to facilitate artificial water wave generation.

### RELATED APPLICATION

This application claims the benefit of U.S. Provisional Application No. 63/730,359, filed Dec. 10, 2024, the disclosure of which is incorporated herein by reference in its entirety.

The examples discussed in the present disclosure are related to water wave image processing, water wave generation, and water wave testing.

### BACKGROUND

Unless otherwise indicated herein, the materials described herein are not prior art to the claims in the present application and are not admitted to be prior art by inclusion in this section.

Surfing is a popular sport throughout the world. Because of its popularity, many surfers travel to remote areas in search of water waves having specific characteristics. However, remote travel is not practical for a lot of casual surfers. To provide water waves in a controlled setting, water wave designers and testers attempt to recreate the water waves in various ways. Therefore, methods for designing water waves using computer technology may be useful.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

In some examples, a device for image processing of a water wave may include an image capture device and a processing device. The image capture device may capture water wave images, in which the water wave images may include water wave image data based on one or more time instances. The processing device may compute a water wave model using the water wave image data; compute artificial water wave parameters using the water wave model; and compute artificial water wave generator input using the artificial water wave parameters, in which the artificial water wave generator input may be used to facilitate artificial water wave generation.

In some examples, a device for generating an artificial water wave may include a processing device and an artificial water wave generator. The processing device may compute a water wave model using water wave image data values; compute artificial water wave parameters using the water wave model; and compute artificial water wave generator input using the artificial water wave parameters. The artificial water wave generator may generate an artificial water wave based on the artificial water wave generator input.

In some examples, a device for testing a water wave may include a processing device. The processing device may compute artificial water wave generator input, in which the artificial water wave generator input is based on artificial water wave parameters. The processing device may determine a safety profile for the artificial water wave based on the artificial water wave generator input. The processing device may determine a performance profile for the artificial water wave based on the artificial water wave generator input, in which the performance profile is computed using one or more performance characteristics of the water wave including height, shape, steepness, speed, peel angle, power, period, or wavelength. The processing device may compute a test result based on one or more of the safety profile and the performance profile.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Examples will be described and explained with additional specificity and detail through the use of the accompanying drawings in which:

FIG. 1 illustrates an example block diagram for water wave image processing, water wave generation, and water wave testing.

FIG. 2 illustrates a process flow of water wave image processing.

FIG. 3 illustrates a process flow of water wave generation.

FIG. 4 illustrates a process flow of water wave testing.

FIG. 5 illustrates a process flow of water wave image processing.

FIG. 6 illustrates a diagrammatic representation of a machine in the example form of a computing device within which a set of instructions, for causing the machine to perform any one or more of the methods discussed herein, may be executed.

### DESCRIPTION

Water wave simulation, generation, and testing may be used in a lot of different aquatic sports and water-based recreational activities. For example, water wave generation may be used in boat racing (e.g., canoeing, rafting, and sailing), towed water sports (e.g., tubing, water skiing), board-sports (e.g., surfing, windsurfing), bodysurfing, or the like. In some cases, water waves may be provided naturally in the ocean. However, weather conditions may impact the availability of the ocean for aquatic sports. Furthermore, the performance characteristics of the water wave (e.g., height, shape, steepness, speed, peel angle, power, period, wavelength, etc.) may vary from day to day, from event to event, or from aquatic participant to aquatic participant. Therefore, water wave generation in a controlled setting may be useful for these activities.

Water wave design has a few limitations. The water waves that exist in nature may be difficult to recreate manually in a controlled setting. A section of a wave may be difficult to recreate. For example, a renowned natural water wave may have a famous section that a designer/tester may want to recreate, and/or the designer/test may want to add a section of the wave to another wave to generate a composite wave.

Furthermore, even when a natural water wave and/or water wave section may be recreated, the process is labor and time-intensive for water wave designers and water wave testers. The water wave design and testing process may rely on the skill of the water wave designer and the water wave tester rather than on a standardized process that may be transferred from one water wave designer/tester to another water wave designer/tester.

Other water wave design limitations include the safety of the water wave generation and testing which can limit its attractiveness to potential patrons and result in risk for the commercial viability of the process. Furthermore, even when safety is not considered, the accuracy and reproducibility of water wave designs may be limited. The limitation in water wave design may also deter potential patrons who may use specific water wave designs. Finally, the lack of standardized water waves may deter innovation because of the process involved in attempting to generate water waves having different characteristics.

Technician-based analysis of ocean water wave patterns may be used for manually designing artificial water waves but may be an arduous process. Furthermore, water wave testing by water wave testers and surfers may be used to establish safety for prospective patrons. However, these processes do not use image/video analysis of water waves nor do these processes use artificial intelligence (AI). Rather, the existing processes for water wave design and testing use a manual and empirical water wave design which may constrain the marketability of aquatic recreation that includes water waves. A manual design process is empirically intensive, relies on technician expertise, and lacks accuracy which may result in a water wave design with low performance and potential hazards. Thus, the manual design process may reduce water wave reliability and reduce commercial viability. Furthermore, the manual design process may not use technological tools (e.g., machine learning, AI) that have been developed in other fields.

In some examples, computer-aided water wave design may include analyzing videos and images of ocean water waves to: (i) map the water wave and/or water wave section using a three-dimensional model, and (ii) convert the three-dimensional model into artificial water wave parameters that may be used to generate the water wave and/or water wave section using a water wave generator. The mapped water waves and/or water wave sections may be added to a water wave library. The water wave library may be used to generate water waves that have not existed in nature by blending the water wave sections and the artificial water wave parameters, as stored in the water wave library, using artificial intelligence. In some examples, the water waves may be generated with or without input from a user.

Thus, water waves having high performance characteristics, high safety characteristics, and low power consumption may be designed using an automated and computer-aided process for water wave image processing, water wave generation, and water wave testing. Using a computer-aided process may: (i) facilitate the speed of the design process, which may allow for real-time design, (ii) provide enhanced potential for water wave design, analysis, generation, and testing, (iii) allow a designer to manually tune the processed water waves to refine wave designs, and (iv) provide enhanced safety for prospective patrons.

Examples of the present disclosure will be explained with reference to the accompanying drawings.

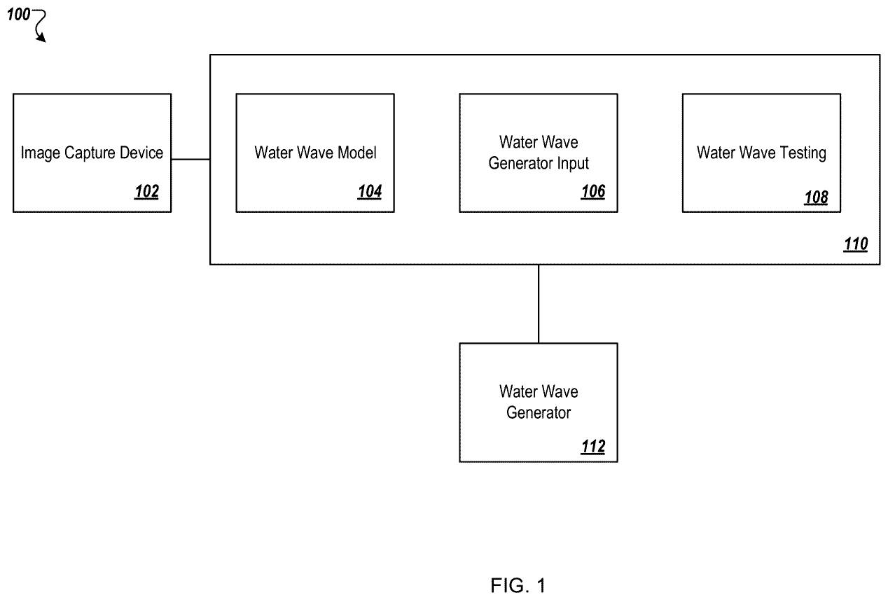

FIG. 1 illustrates a device 100 for image processing of a water wave that may comprise an image capture device 102 and a processing device 110. The image capture device 102 may capture and/or import water wave images and/or video. The water wave images and/or video may include water wave image data based on one or more time instances.

The image capture device 102 may include any suitable device used in image processing for capturing a digital image. In one example, the image capture device 102 may include, but is not limited to, one or more of: a digital camera, a digital video camera, an image scanner, a radar, microwave sensor, a sonar, any other suitable digital sensor (e.g., a charge-coupled device (CCD), active pixel sensor, or quanta image sensor). In addition or alternatively, drones may be used to capture the digital images and/or video.

In some examples, a processing device 110 may determine the water wave image data based on one or more water wave images and/or water wave videos. In one example, the water wave images may be ocean water wave images and/or ocean water wave videos. A water wave image may include one or more water wave sections. A water wave section of a water wave image may include one or more properties including one or more of: water wave height; water wave shape, water wave steepness; water wave speed, water wave peel angle; water wave power, water wave period, water wave wavelength, or the like. In addition or alternatively, other input sources may be used. For example, real measurements at the wave break may be used to guide the model. For example, pressure measurement may be used to compute wave height.

Different image angles may be used to compute the one or more properties. For example, water wave shape and/or water wave steepness may be computed based on the cross section and/or by using photos and/or videos capturing images in a sideways orientation. In addition or alternatively, the wave lip shape may be used to determine the shape of the wave when photos and/or videos are captured from a front of the wave. In addition or alternatively, the water wave speed and/or the water wave peel angle may be computed by capturing the overview (i.e., a video/photo from the top of the wave) and measuring the angle between the crest and whitewater path. In addition or alternatively, the water wave power may be computed based on e.g., white water behavior and/or computed based on one or more of the water wave height, water wave shape, and/or water wave steepness. The plurality of water wave sections may be divided in a profile direction of the water wave to facilitate the generation of artificial water wave parameters.

To compute the water wave power, the wave power formula may be used in which the wave energy flux may be:

$$P = ( {ρ g}^{2} / 64 π ) {H}_{m 0}^{2} {T}_{e}$$

in which P may be the wave energy flux per unit of wave crest length, Hₘ₀ may be the significant wave height, Tₑ may be the wave energy period, ρ may be the water density, and g may be the acceleration by gravity.

In some examples, the processing device 110 may compute a water wave model 104 using the water wave image data. The water wave model 104 may be any suitable model for simulating a water wave over a period of time. In one example, the model may use a shallow water equation. In addition or alternatively, the model may be a boussinesq model. The shallow water equations may include:

$$\frac{\partial ( ρ η )}{\partial t} + \frac{\partial ( ρ η μ )}{\partial x} + \frac{\partial ( ρην )}{\partial y} = 0 ; \qquad ( 1 )$$

$$\frac{\partial ( ρημ )}{\partial t} + \frac{\partial }{\partial x} ( ρ η {μ}^{2} + ( \frac{1}{2} ) {ρ g η}^{2} ) + \frac{\partial ( ρημν )}{\partial y} = 0 ; \qquad ( 2 )$$

$$\frac{\partial ( ρην )}{\partial t} + \frac{\partial }{\partial y} ( {ρην}^{2} + ( \frac{1}{2} ) {ρ g η}^{2} ) + \frac{\partial ( ρημν )}{\partial x} = 0 , \qquad ( 3 )$$

in which η may be the total fluid column height, the 2D vector (μ, v) may be the fluid's horizontal flow velocity and ρ may be the fluid density. The non-conservative form of the shallow water equations may be used. The boussinesq model may include

$$\frac{{\partial }^{2} η}{\partial {t}^{2}} g h \frac{{\partial }^{2} η}{\partial {x}^{2}} - g h \frac{{\partial }^{2}}{\partial {x}^{2}} ( ( \frac{3}{2} ) \frac{{η}^{2}}{h} + ( \frac{1}{3} ) {h}^{2} \frac{{\partial }^{2} η}{\partial {x}^{2}} ) = 0 ,$$

in which h may be the water depth, η may be the free surface elevation, and g may be the gravitational acceleration.

The water wave image data may be processed using any suitable image processing algorithm including one or more of: a classification algorithm, a feature extraction algorithm, a multi-scale signal analysis algorithm, or a projection algorithm. In some examples, different digital image processing techniques may be used including one or more of anisotropic diffusion, hidden markov models, image editing, image restoration, independent component analysis, linear filtering, neural networks, pixilation, point feature matching, principal component analysis, self-organizing maps, wavelets, or the like. In some examples, the model may include one or more of an artificial neural network (ANN) model, a decision tree, a support-vector machine, regression analysis, Bayesian networks, Gaussian processes, or the like. In some examples, the water wave model 104 may be generated using a data set including training data.

The water wave model 104 may be computed using additional water wave sensor data. In one example, the additional water wave sensor data may include water wave sensor data measured by a wave buoy (e.g., a global positioning system (GPS) wave buoy or a gravity-acceleration-type wave buoy).

The processing device 110 may compute artificial water wave parameters using the water wave model 104. The artificial water wave parameters may be computed using machine learning including one or more of supervised learning, unsupervised learning, semi-supervised learning, reinforcement learning, dimensionality reduction, or the like.

In some examples, the processing device 110 may compute artificial water wave generator input 106 using the artificial water wave parameters, in which the artificial water wave generator input 106 is used to facilitate artificial water wave generation. A water wave may include water wave sections which may include various properties including one or more of: water wave height, water wave shape, water wave steepness, water wave speed, water wave peel angle, or water wave power, water wave period, water wave wavelength, or the like. In some examples, the water wave image data may include one or more of: water wave height data, water wave shape data, water wave steepness data, water wave speed data, water wave peel angle data, water wave power data, water wave period data, or water wave wavelength data. The three dimensional model water wave may be analyzed in the time domain to determine the properties of the water wave sections.

The artificial water wave parameters may include one or more of: an artificial water wave height parameter, an artificial water wave shape parameter, an artificial water wave steepness parameter, an artificial water wave speed parameter, an artificial water wave peel angle parameter, or an artificial water wave power parameter. In one example, the artificial water wave height may computed using the lowest point to the highest point of the wave. In one example, the artificial water wave shape or the artificial steepness may be computed based on the cross-section of the water wave. In one example, one or more of the artificial water wave speed, the artificial water wave peel angle, or the artificial water wave power may be computed by analyzing the time domain. The peel angle may be computed using a top view of a wave and/or wave section in which the shoulder line may be compared to the whitewater line to compute the angle of the wave and/or wave section.

The processing device 110 may send the artificial water wave parameters to a water wave database for storage. In some examples, the processing device 110 may retrieve first artificial water wave parameters from the water wave database, retrieve second artificial water wave parameters from the water wave database, and generate a composite artificial water wave generator input 106 based on the first artificial water wave parameters and the second artificial water wave parameters.

In some examples, the processing device 110 may receive input data used to compute additional artificial water wave parameters, generate a composite artificial water wave generator input 106 based on the artificial water wave parameters and the additional artificial water wave parameters. In some examples, the processing device 110 may compute the artificial water wave parameters in real time.

In some examples, a device for generating an artificial water wave may include a processing device 110 that may compute a water wave model 104 using water wave image data values, compute artificial water wave parameters using the water wave model 104, and compute artificial water wave generator input 106 using the artificial water wave parameters. The device may include an artificial water wave generator 112 to generate an artificial water wave based on the artificial water wave generator input 106.

The image processing data may analyze the different images and videos to capture wave characteristics over time and compute e.g., the free surface. When the free surface has been computed, source terms may be computed by reversing the equations. When the source term solution (e.g., source to create the wave capture in video) is calculated, the source term solution may be further reversed to calculate the pressures in the caisson to create the source term. When the pressures are computed, the valves angles (e.g., exhaust and intake) may be computed. Furthermore, caisson profiles for the caisson may be computed.

The pressure in the caisson may be computed using the valve opening angles. For example, the flow through an orifice may be computed using q=C_{d}A((2/p)Δp)\hat{ }(½) in which A may be the cross section of the orifice, Δp may be the pressure drop over the orifice, and p may be the density of the fluid. The discharge coefficient, C_{d}, may be a constant. The pressure in the caisson may be used to compute water movements e.g., using a model of a driven harmonic oscillator.

Therefore, when a water wave has been generated in 3D over time, the source terms used to create the wave may be computed (e.g., caisson outlet speeds). For the source terms, pressure in the caisson and valve opening angles may be computed based on a mathematical model. Source terms may be computed by using one or more of the shallow water equations or the boussinesq model. In one example, the source term may be a velocity of the caisson. A harmonic oscillator model may be used to model water oscillating in the caissons. Based on the velocities in the caissons, the pressure to be applied to the water surface to reach the velocities in the caissons may be computed. Based on the pressure, the valve angle may be computed (because the pressure in the plenum may be based on the valve characteristics). Consequently, the image and/or video data may be used to generate an artificial wave.

The processing device 110 may be further operable to compute additional artificial water wave parameters using an additional water wave model 104. The additional water wave model 104 may be computed using additional water wave image data values. In some examples, the processing device 110 may compute a composite artificial water wave generator input 106 based on the artificial water wave parameters and the additional artificial water wave parameters. In some examples, the processing device 110 may generate a composite artificial water wave using the composite artificial water wave generator input 106. A composite artificial water wave and/or composite artificial water wave section may be based on first artificial water wave parameters and second artificial water wave parameters in which the first artificial water wave parameters are different from the second artificial water wave parameters.

The processing device 110 may receive input data used to identify additional artificial water wave parameters. In some examples, the processing device 110 may compute a composite water wave generator input based on the artificial water wave parameters and the additional artificial water wave parameters. In some examples, the processing device 110 may be further operable to generate a composite artificial water wave using the composite artificial water wave generator input 106. In some examples, the processing device 110 may compute the artificial water wave generator input 106 in real time.

A device for testing a water wave (e.g., using water wave testing block 108) may include a processing device 110. The processing device 110 may compute artificial water wave generator input 106. The artificial water wave generator input 106 may be based on artificial water wave parameters. The processing device 110 may determine a safety profile for the artificial water wave based on the artificial water wave generator input 106. The processing device 110 may determine a performance profile for the artificial water wave based on the artificial water wave generator input 106. The performance profile may be computed using one or more performance characteristics of the water wave including height, shape, steepness, speed, peel angle, power, period, or wavelength. The performance profile may be used in combination with an optimization algorithm to maximize wave height or steepness and/or minimize power consumption.

The safety profile may include any suitable metrics related to the safety of the water wave. In some examples, the safety profile may be generated using machine learning based on a safety model generated based on a training dataset.

The performance profile may include any suitable metrics related to the performance of the water wave. In some examples, the performance profile may be generated using machine learning based on a performance model generated based on a training dataset.

The processing device 110 may compute a test result based on one or more of the safety profile and the performance profile. In some examples, the processing device 110 may be further operable to adjust, based on the test result, one or more of the artificial water wave parameters or the artificial water wave generator input 106. In some examples, the processing device 110 may compute an additional test result after the one or more of the artificial water wave parameters or the artificial water wave generator input 106 has been adjusted.

The artificial water wave parameters may include one or more of: an artificial water wave height parameter, an artificial water wave shape parameter, an artificial water wave steepness parameter, an artificial water wave speed parameter, an artificial water wave peel angle parameter, an artificial water wave power parameter, an artificial water wave period parameter, or an artificial water wave wavelength parameter.

The processing device 110 may send the artificial water parameters having one or more of the performance profile or the safety profile to a water wave database for storage. In some examples, the processing device 110 may be further operable to retrieve first artificial water wave parameters from the water wave database having one or more of a first performance profile or a first safety profile. In some examples, the processing device 110 may retrieve second artificial water wave parameters from the water wave database having one or more of a second performance profile or a second safety profile.

The processing device 110 may determine a composite safety profile or a composite performance profile for a composite artificial water wave based on composite artificial water wave generator input 106. In one example, the composite artificial water wave generator input 106 may be computed based on the first artificial water wave parameters and the second artificial water wave parameters.

The processing device 110 may compute the safety profile based on a safety profile data-set or compute the performance profile based on a performance profile data-set.

Water waves may be generated in accordance with various use cases. In some examples, the water waves may be generated to mimic ocean water waves from e.g., remote areas of the world. In some examples, a user may design their own water wave by providing a video of the water wave which may be generated using the water waver generator. In some examples, water wave generators may randomly send waves to a lagoon to recreate the randomness found in the ocean.

Water waves may be generated to provide high performance training and/or learning. In one example, water waves may be generated based on a performance level of a targeted user (e.g., from beginner to professional).

Water wave generation may be used for different events and sports. In some examples, sports betting may be integrated into water wave acquisition, generation, and testing. In some examples, interactivity with spectators may be enhanced by generating water waves based on spectator participation (e.g., based on a vote of spectators).

Modifications, additions, or omissions may be made to the components of FIG. 1 without departing from the scope of the present disclosure.

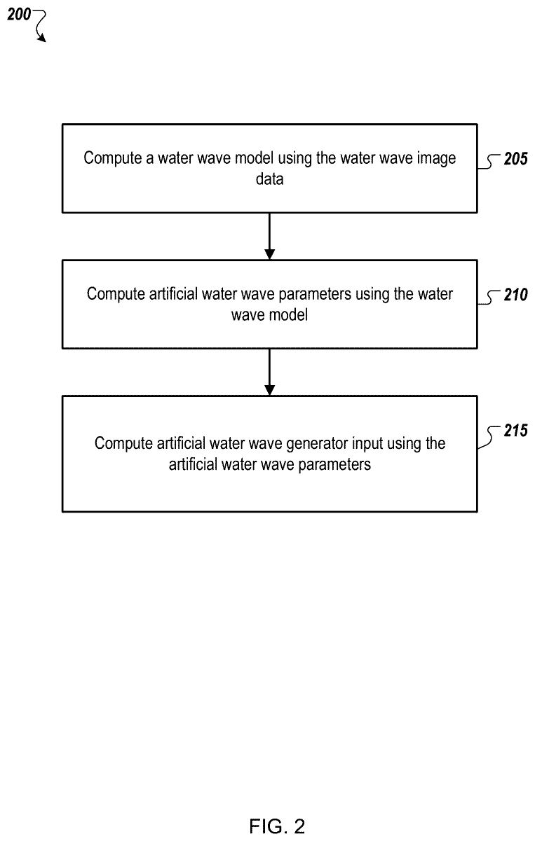

FIG. 2 illustrates a process flow of an example method 200 of image processing of a water wave, in accordance with at least one example described in the present disclosure. The method 200 may be arranged in accordance with at least one example described in the present disclosure.

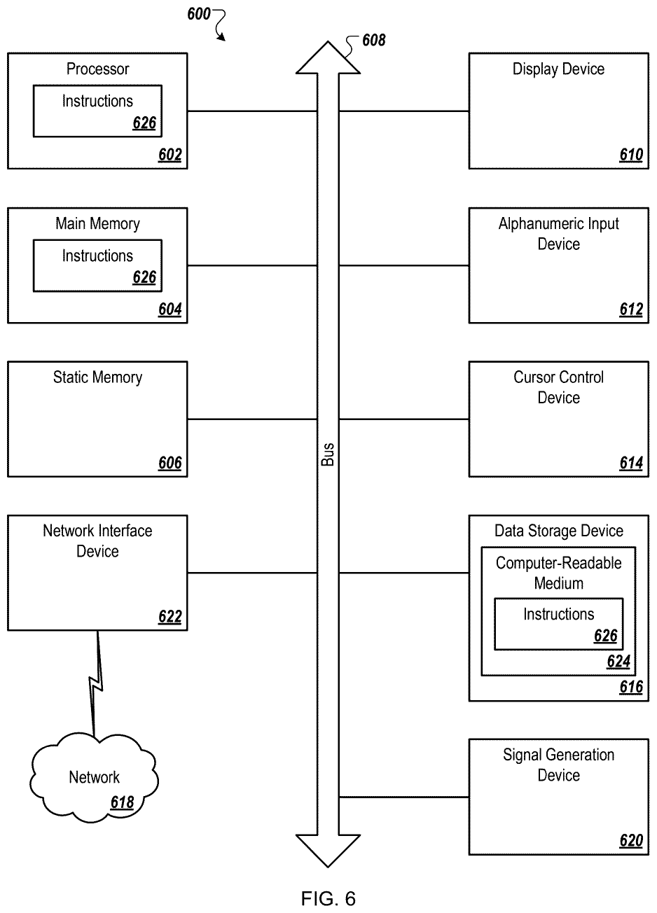

The method 200 may be performed by processing logic that may include hardware (circuitry, dedicated logic, etc.), software (such as is run on a computer system or a dedicated machine), or a combination of both, which processing logic may be included in the processing device 602 of FIG. 6, or another device, combination of devices, or systems.

The method 200 may begin at block 205 where the processing logic may compute a water wave model using the water wave image data.

At block 210, the processing logic may compute artificial water wave parameters using the water wave model.

At block 215, the processing logic may compute artificial water wave generator input using the artificial water wave parameters, wherein the artificial water wave generator input is used to facilitate artificial water wave generation.

Modifications, additions, or omissions may be made to the method 200 without departing from the scope of the present disclosure. For example, in some examples, the method 200 may include any number of other components that may not be explicitly illustrated or described.

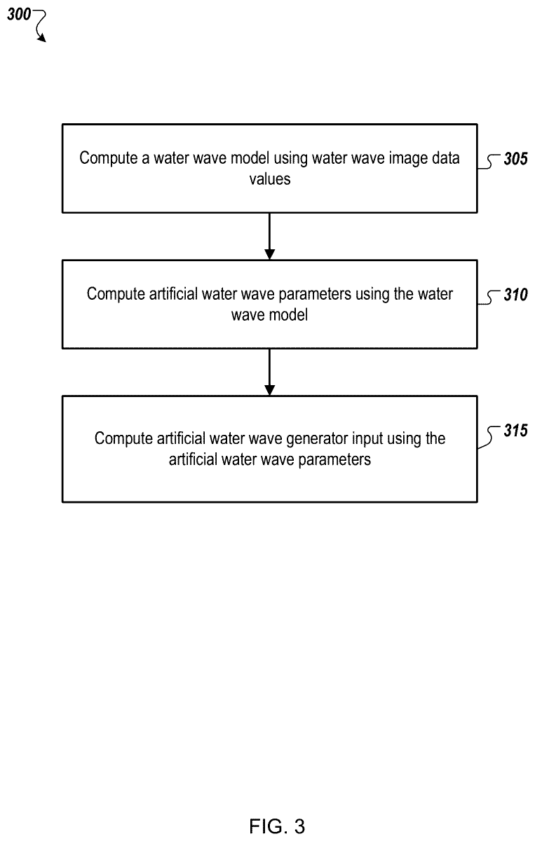

FIG. 3 illustrates a process flow of an example method 300 that may be used for generating an artificial water wave, in accordance with at least one example described in the present disclosure. The method 300 may be arranged in accordance with at least one example described in the present disclosure.

The method 300 may be performed by processing logic that may include hardware (circuitry, dedicated logic, etc.), software (such as is run on a computer system or a dedicated machine), or a combination of both, which processing logic may be included in the processing device 602 of FIG. 6, or another device, combination of devices, or systems.

The method 300 may begin at block 305 where the processing logic may compute a water wave model using water wave image data values.

At block 310, the processing logic may compute artificial water wave parameters using the water wave model.

At block 315, the processing logic may compute artificial water wave generator input using the artificial water wave parameters.

Modifications, additions, or omissions may be made to the method 300 without departing from the scope of the present disclosure. For example, in some examples, the method 300 may include any number of other components that may not be explicitly illustrated or described.

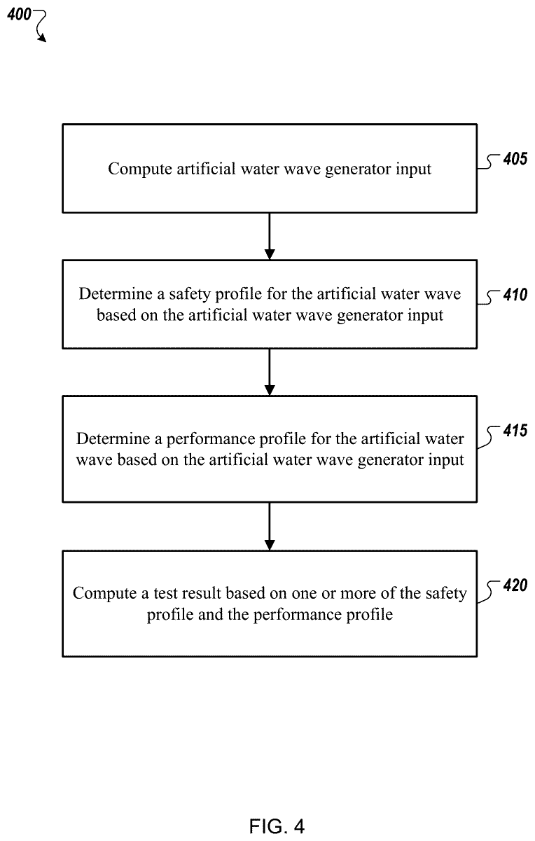

FIG. 4 illustrates a process flow of an example method 400 that may be used for testing a water wave, in accordance with at least one example described in the present disclosure. The method 400 may be arranged in accordance with at least one example described in the present disclosure.

The method 400 may be performed by processing logic that may include hardware (circuitry, dedicated logic, etc.), software (such as is run on a computer system or a dedicated machine), or a combination of both, which processing logic may be included in the processing device 602 of FIG. 6, or another device, combination of devices, or systems.

The method 400 may begin at block 405 where the processing logic may compute artificial water wave generator input, in which the artificial water wave generator input is based on artificial water wave parameters.

At block 410, the processing logic may determine a safety profile for the artificial water wave based on the artificial water wave generator input.

At block 415, the processing logic may determine a performance profile for the artificial water wave based on the artificial water wave generator input.

At block 420, the processing logic may compute a test result based on one or more of the safety profile and the performance profile.

Modifications, additions, or omissions may be made to the method 400 without departing from the scope of the present disclosure. For example, in some examples, the method 400 may include any number of other components that may not be explicitly illustrated or described.

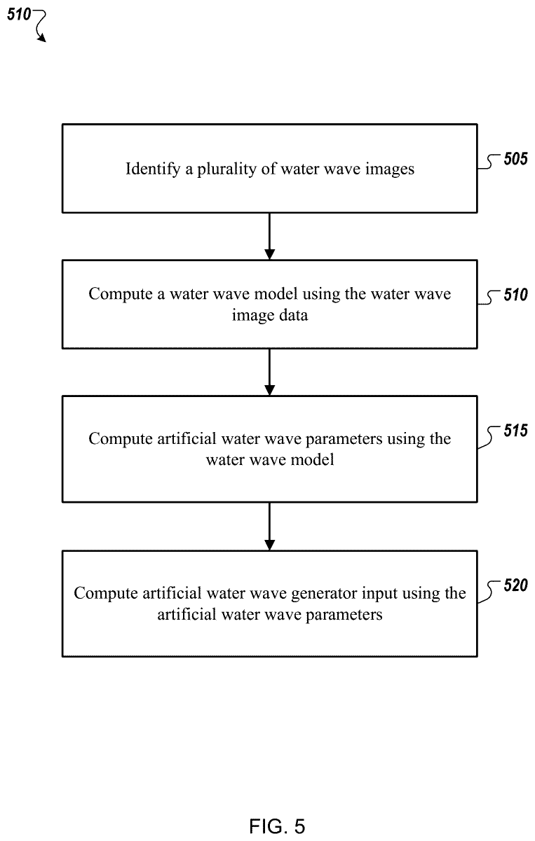

FIG. 5 illustrates a process flow of an example method 500 that may be used for testing a water wave, in accordance with at least one example described in the present disclosure. The method 500 may be arranged in accordance with at least one example described in the present disclosure.

The method 500 may be performed by processing logic that may include hardware (circuitry, dedicated logic, etc.), software (such as is run on a computer system or a dedicated machine), or a combination of both, which processing logic may be included in the processing device 602 of FIG. 6, or another device, combination of devices, or systems.

The method 500 may begin at block 505 where the processing logic may identify a plurality of water wave images, in which the plurality of water wave images comprises water wave image data based on one or more time instances.

At block 510, the processing logic may compute a water wave model using the water wave image data.

At block 515, the processing logic may compute artificial water wave parameters using the water wave model.

At block 520, the processing logic may compute artificial water wave generator input using the artificial water wave parameters, wherein the artificial water wave generator input is used to facilitate artificial water wave generation.

Modifications, additions, or omissions may be made to the method 500 without departing from the scope of the present disclosure. For example, in some examples, the method 500 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

FIG. 6 illustrates a diagrammatic representation of a machine in the example form of a computing device 600 within which a set of instructions, for causing the machine to perform any one or more of the methods discussed herein, may be executed. The computing device 600 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative examples, the machine may be connected (e.g., networked) to other machines in a local area network (LAN), an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 600 includes a processing device (e.g., a processor) 602, a main memory 604 (e.g., read-only memory (ROM), flash memory, dynamic random access memory (DRAM) such as synchronous DRAM (SDRAM)), a static memory 606 (e.g., flash memory, static random access memory (SRAM)) and a data storage device 616, which communicate with each other via a bus 608.

Processing device 602 represents one or more general-purpose processing devices such as a microprocessor, central processing unit, or the like. More particularly, the processing device 602 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 602 may also include one or more special-purpose processing devices such as an application specific integrated circuit (ASIC), a field programmable gate array (FPGA), a digital signal processor (DSP), network processor, or the like. The processing device 602 is operable to execute instructions 626 for performing the operations and steps discussed herein.

The computing device 600 may further include a network interface device 622 which may communicate with a network 618. The computing device 600 also may include a display device 610 (e.g., a liquid crystal display (LCD) or a cathode ray tube (CRT)), an alphanumeric input device 612 (e.g., a keyboard), a cursor control device 614 (e.g., a mouse) and a signal generation device 620 (e.g., a speaker). In at least one example, the display device 610, the alphanumeric input device 612, and the cursor control device 614 may be combined into a single component or device (e.g., an LCD touch screen).

The data storage device 616 may include a computer-readable storage medium 624 on which is stored one or more sets of instructions 626 embodying any one or more of the methods or functions described herein. The instructions 626 may also reside, completely or at least partially, within the main memory 604 and/or within the processing device 602 during execution thereof by the computing device 600, the main memory 604 and the processing device 602 also constituting computer-readable media. The instructions may further be transmitted or received over a network 618 via the network interface device 622.

While the computer-readable storage medium 624 is shown in an example to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

### EXAMPLES

In one example, a computer-implemented method may include identifying a plurality of water wave images, wherein the plurality of water wave images comprises water wave image data based on one or more time instances; computing a water wave model using the water wave image data; computing artificial water wave parameters using the water wave model; and computing artificial water wave generator input using the artificial water wave parameters, wherein the artificial water wave generator input is used to facilitate artificial water wave generation.

The computer-implemented method may include sending the artificial water wave parameters to a water wave database for storage. The computer-implemented method may include: retrieving first artificial water wave parameters from the water wave database; retrieving second artificial water wave parameters from the water wave database; and generating a composite artificial water wave generator input based on the first artificial water wave parameters and the second artificial water wave parameters. The computer-implemented method may include receiving input data used to compute additional artificial water wave parameters; and generating a composite artificial water wave generator input based on the artificial water wave parameters and the additional artificial water wave parameters. The computer-implemented method may include: receiving input data used to identify additional artificial water wave parameters; computing a composite water wave generator input based on the artificial water wave parameters and the additional artificial water wave parameters; and generating a composite artificial water wave using the composite artificial water wave generator input. The computer-implemented method may include computing the artificial water wave generator input in real time.

In some examples, the different components, modules, engines, and services described herein may be implemented as objects or processes that execute on a computing system (e.g., as separate threads). While some of the systems and methods described herein are generally described as being implemented in software (stored on and/or executed by hardware), specific hardware implementations or a combination of software and specific hardware implementations are also possible and contemplated.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although examples of the present disclosure have been described in detail, it should be understood that the various changes, substitutions, and alterations could be made hereto without departing from the spirit and scope of the present disclosure.

What is claimed is:

1. A device for image processing of a water wave, comprising:
an image capture device operable to capture a plurality of water wave images, wherein the plurality of water wave images comprises water wave image data based on one or more time instances; and
a processing device operable to:
compute a water wave model using the water wave image data;
compute artificial water wave parameters using the water wave model; and
compute artificial water wave generator input using the artificial water wave parameters, wherein the artificial water wave generator input is used to facilitate artificial water wave generation.

2. The device of claim 1, wherein the water wave image data comprises a plurality of water wave sections.

3. The device of claim 2, wherein the plurality of water wave sections are divided in a profile direction to facilitate generation of artificial water wave parameters.

4. The device of claim 1, wherein the water wave image data includes one or more of:
water wave height data, water wave shape data, water wave steepness data, water wave speed data, water wave peel angle data, water wave power data, water wave period data, or water wave wavelength data.

5. The device of claim 1, wherein the artificial water wave parameters include one or more of: an artificial water wave height parameter, an artificial water wave shape parameter, an artificial water wave steepness parameter, an artificial water wave speed parameter, an artificial water wave peel angle parameter, an artificial water wave power parameter, an artificial water wave period parameter, or an artificial water wave wavelength parameter.

6. The device of claim 1, wherein the water wave images are one or more of ocean water wave images or ocean water wave videos.

7. The device of claim 1, wherein the processing device is further operable to send the artificial water wave parameters to a water wave database for storage.

8. The device of claim 1, wherein the processing device is further operable to:
retrieve first artificial water wave parameters from a water wave database;
retrieve second artificial water wave parameters from the water wave database; and
generate a composite artificial water wave generator input based on the first artificial water wave parameters and the second artificial water wave parameters.

9. The device of claim 1, wherein the processing device is further operable to:
receive input data used to compute additional artificial water wave parameters; and
generate a composite artificial water wave generator input based on the artificial water wave parameters and the additional artificial water wave parameters.

10. The device of claim 1, wherein the processing device is further operable to:
compute the artificial water wave parameters in real time.

11. A device for generating an artificial water wave, comprising:
a processing device operable to:
compute a water wave model using water wave image data values;
compute artificial water wave parameters using the water wave model; and
compute artificial water wave generator input using the artificial water wave parameters; and
an artificial water wave generator operable to generate an artificial water wave based on the artificial water wave generator input.

12. The device of claim 11, wherein the processing device is further operable to:
compute additional artificial water wave parameters using an additional water wave model, wherein the additional water wave model is computed using additional water wave image data values;
compute a composite artificial water wave generator input based on the artificial water wave parameters and the additional artificial water wave parameters; and
generate a composite artificial water wave using the composite artificial water wave generator input.

13. The device of claim 11, wherein the processing device is further operable to:
receive input data used to identify additional artificial water wave parameters;
compute a composite water wave generator input based on the artificial water wave parameters and the additional artificial water wave parameters; and
generate a composite artificial water wave using the composite artificial water wave generator input.

14. The device of claim 11, wherein the processing device is further operable to:
compute the artificial water wave generator input in real time.

15. A device for testing a water wave, comprising:
a processing device operable to:
compute artificial water wave generator input, wherein the artificial water wave generator input is based on artificial water wave parameters; and
determine a safety profile for the artificial water wave based on the artificial water wave generator input;
determine a performance profile for the artificial water wave based on the artificial water wave generator input, wherein the performance profile is computed using one or more performance characteristics of the water wave including height, shape, steepness, speed, peel angle, power, period, or wavelength; and
compute a test result based on one or more of the safety profile and the performance profile.

16. The device of claim 15, wherein the processing device is further operable to:
adjust, based on the test result, one or more of the artificial water wave parameters or the artificial water wave generator input; and
compute an additional test result after the one or more of the artificial water wave parameters or the artificial water wave generator input has been adjusted.

17. The device of claim 15, wherein the artificial water wave parameters include one or more of: an artificial water wave height parameter, an artificial water wave shape parameter, an artificial water wave steepness parameter, an artificial water wave speed parameter, an artificial water wave peel angle parameter, an artificial water wave power parameter, an artificial water wave period parameter, or an artificial water wave wavelength parameter.

18. The device of claim 15, wherein the processing device is further operable to send the artificial water parameters having one or more of the performance profile or the safety profile to a water wave database for storage.

19. The device of claim 15, wherein the processing device is further operable to:
retrieve first artificial water wave parameters from a water wave database having one or more of a first performance profile or a first safety profile;
retrieve second artificial water wave parameters from the water wave database having one or more of a second performance profile or a second safety profile; and
determine a composite safety profile or a composite performance profile for a composite artificial water wave based on composite artificial water wave generator input, wherein the composite artificial water wave generator input is computed based on the first artificial water wave parameters and the second artificial water wave parameters.

20. The device of claim 15, wherein the processing device is further operable to:
compute the safety profile based on a safety profile data-set; or
compute the performance profile based on a performance profile data-set.
